(19) United States
(12) Patent Application Publication
(10) Pub. No.: US 2009/0272438 A1
(43) Pub. Date: Nov. 5, 2009

(54) Strain Balanced Multiple Quantum Well Subcell In Inverted Metamorphic Multijunction Solar Cell

(75) Inventor: Arthur Cornfeld, Sandia Park, NM (US)

Correspondence Address: EMCORE CORPORATION, 1600 EUBANK BLVD, S.E., ALBUQUERQUE, NM, 87123, US

(73) Assignee: Emcore Corporation, Albuquerque, NM (US)

(21) Appl. No.: 12/253,051

(22) Filed: Oct. 16, 2008

Related U.S. Application Data
(60) Provisional application No. 61/050,450, filed on May 5, 2008.

(51) Int. Cl. H01L 31/0304; H01L 31/18

(52) U.S. Cl. 136/261; 438/94; 257/E31.019

(57) ABSTRACT

A method of manufacturing a solar cell by providing a first semiconductor substrate for the epitaxial growth of semiconductor material; forming a first subcell on the substrate with a first semiconductor material with a first band gap and a first lattice constant; forming a second subcell with a second semiconductor material with a second band gap and a second lattice constant, wherein the second band gap is less than the first band gap and the second lattice constant is greater than the first lattice constant; the second subcell including a strain balanced quantum well structure; and forming a lattice constant transition material positioned between the first subcell and the second subcell, the lattice constant transition material having a lattice constant that changes gradually from the first lattice constant to the second lattice constant.

### REFERENCE TO RELATED APPLICATIONS

This application is related to co-pending U.S. patent application Ser. No. 11/288,315 filed Apr. 18, 2007.

This application is related to co-pending U.S. patent application Ser. No. 12/190,449 filed Aug. 12, 2008.

This application is related to co-pending U.S. patent application Ser. No. 12/187,477 filed Aug. 7, 2008.

This application is related to co-pending U.S. patent application Ser. No. 12/218,582 filed Jul. 18, 2008.

This application is related to co-pending U.S. patent application Ser. No. 12/123,864 filed May 20, 2008.

This application is related to co-pending U.S. patent application Ser. No. 12/102,550 filed Apr. 14, 2008.

This application is related to co-pending U.S. patent application Ser. No. 12/047,842, and U.S. Ser. No. 12/047,944, filed Mar. 13, 2008.

This application is related to co-pending U.S. patent application Ser. No. 12/023,772, filed Jan. 31, 2008.

This application is related to co-pending U.S. patent application Ser. No. 11/956,069, filed Dec. 13, 2007.

This application is also related to co-pending U.S. patent application Ser. Nos. 11/860,142 and 11/860,183 filed Sep. 24, 2007.

This application is also related to co-pending U.S. patent application Ser. No. 11/836,402 filed Aug. 8, 2007.

This application is also related to co-pending U.S. patent application Ser. No. 11/616,596 filed Dec. 27, 2006.

This application is also related to co-pending U.S. patent application Ser. No. 11/614,332 filed Dec. 21, 2006.

This application is also related to co-pending U.S. patent application Ser. No. 11/445,793 filed Jun. 2, 2006.

This application is also related to co-pending U.S. patent application Ser. No. 11/500,053 filed Aug. 7, 2006.

### GOVERNMENT RIGHTS STATEMENT

This invention was made with government support under Contract No. FA9453-04-2-0041 awarded by the U.S. Air Force. The Government has certain rights in the invention.

### BACKGROUND OF THE INVENTION

1. Field of the Invention

The present invention relates to the field of semiconductor devices, and to fabrication processes and devices such as multifunction solar cells based on III-V semiconductor compounds including a metamorphic layer. Such devices are also known as inverted metamorphic multifunction solar cells.

2. Description of the Related Art

Photovoltaic cells, also called solar cells, are one of the most important new energy sources that have become available in the past several years. Considerable effort has gone into solar cell development. As a result, solar cells are currently being used in a number of commercial and consumer-oriented applications. While significant progress has been made in this area, the requirement for solar cells to meet the needs of more sophisticated applications has not kept pace with demand. Applications such as concentrator terrestrial power systems and satellites used in data communications have dramatically increased the demand for solar cells with improved power and energy conversion characteristics.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as the payloads become more sophisticated, solar cells, which act as the power conversion devices for the on-board power systems, become increasingly more important.

Solar cells are often fabricated in vertical, multijunction structures, and disposed in horizontal arrays, with the individual solar cells connected together in a series. The shape and structure of an array, as well as the number of cells it contains, are determined in part by the desired output voltage and current.

Inverted metamorphic solar cell structures such as described in M. W. Wanlass et al., Lattice Mismatched Approaches for High Performance, III-V Photovoltaic Energy Converters (Conference Proceedings of the 31^{st} IEEE Photovoltaic Specialists Conference, Jan. 3-7, 2005, IEEE Press, 2005) present an important conceptual starting point for the development of future commercial high efficiency solar cells. The structures described in such reference present a number of practical difficulties relating to the appropriate choice of materials and fabrication steps, for a number of different layers of the cell.

Prior to the present invention, the materials and fabrication steps disclosed in the prior art have not been adequate to produce a commercially viable and energy efficient solar cell using commercially established fabrication processes for producing an inverted metamorphic multijunction cell structure.

### SUMMARY OF THE INVENTION

A method of forming a multifunction solar cell comprising an upper subcell, a middle subcell, and a lower subcell comprising providing a first substrate for the epitaxial growth of semiconductor material; forming an upper first solar subcell on said first substrate having a first band gap; forming a middle second solar subcell over said first solar subcell having a second band gap smaller than said first band gap; forming a graded interlayer over said second solar cell; forming a lower third solar subcell over said graded interlayer and having a strain balanced quantum well layer, and having a fourth band gap smaller than said second band gap such that said third subcell is lattice mismatched with respect to said second subcell; attaching a surrogate second substrate over said third solar subcell; and removing said first substrate.

In another aspect, the present invention provides a method of manufacturing a solar cell by providing a first semiconductor substrate for the epitaxial growth of semiconductor material; forming a first subcell on said substrate comprising a first semiconductor material with a first band gap and a first lattice constant; forming a second subcell comprising a second semiconductor material with a second band gap and a second lattice constant and having a strain balanced quantum well layer, and wherein the second band gap is less than the first band gap and the second lattice constant is greater than the first lattice constant; and forming a lattice constant transition material positioned between the first subcell and the second subcell, said lattice constant transition material having a lattice constant that changes gradually from the first lattice constant to the second lattice constant; attaching a surrogate second substrate over the second subcell; and removing said first substrate.

In another aspect the present invention provides a method of manufacturing a solar cell by providing a first semiconductor substrate; depositing on the first substrate a sequence of layers of semiconductor material forming a solar cell including a strain balanced quantum well layer; mounting a surrogate second substrate on top of the sequence of layers; and removing the first substrate.

In another aspect the present invention provides a method of manufacturing a solar cell by providing a first semiconductor substrate; depositing on the first substrate a sequence of layers of semiconductor material forming a solar cell, including a subcell with an unintentionally doped layer; mounting a surrogate second substrate on top of the sequence of layers; and removing the first substrate.

In another aspect the present invention provides a solar cell comprising a first semiconductor substrate for the epitaxial growth of semiconductor material; a first subcell on the substrate including a first semiconductor material with a first band gap and a first lattice constant; a second subcell including a second semiconductor material with a second band gap and a second lattice constant, wherein the second band gap is less than the first ban gap and the second lattice constant is greater than the first lattice constant; the second subcell including a strain balanced quantum well structure; and a lattice constant transition material positioned between the first subcell and the second subcell, the lattice constant transition material having a lattice constant that changes gradually from the lattice constant to the second lattice constant.

### BRIEF DESCRIPTION OF THE DRAWINGS

The invention will be better and more fully appreciated by reference to the following detailed description when considered in conjunction with the accompanying drawings, wherein:

FIG. 1 is a graph representing the bandgap of certain binary materials and their lattice constants;

FIG. 2 is a cross-sectional view of the solar cell of the invention after the deposition of semiconductor layers on the growth substrate;

FIG. 3 is a cross-sectional view of the solar cell of FIG. 2 after the next process step;

FIG. 4 is a cross-sectional view of the solar cell of FIG. 3 after next process step;

FIG. 5A is a cross-sectional view of the solar cell of FIG. 4 after the next process step in which a surrogate substrate is attached;

FIG. 5B is a cross-sectional view of the solar cell of FIG. 5A after the next process step in which the original substrate is removed;

FIG. 5C is another cross-sectional view of the solar cell of FIG. 5B with the surrogate substrate on the bottom of the Figure;

FIG. 6 is a simplified cross-sectional view of the solar cell of FIG. 5C after the next process step;

FIG. 7 is a cross-sectional view of the solar cell of FIG. 6 after the next process step;

FIG. 8 is a cross-sectional view of the solar cell of FIG. 7 after the next process step;

FIG. 9 is a cross-sectional view of the solar cell of FIG. 8 after the next process step;

FIG. 10A is a top plan view of a wafer in which the solar cells are fabricated;

FIG. 10B is a bottom plan view of a wafer in which the solar cells are fabricated;

FIG. 11 is a cross-sectional view of the solar cell of FIG. 9 after the next process step;

FIG. 12 is a cross-sectional view of the solar cell of FIG. 11 after the next process step;

FIG. 13 is a top plan view of the wafer of FIG. 12 depicting the surface view of the trench etched around the cell, after the next process step;

FIG. 14A is a cross-sectional view of the solar cell of FIG. 12 after the next process step in a first embodiment of the present invention;

FIG. 14B is a cross-sectional view of the solar cell of FIG. 14A after the next process step in a second embodiment of the present invention;

FIG. 15 is a cross-sectional view of the solar cell of FIG. 14B after the next process step in a third embodiment of the present invention;

FIG. 16 is a graph of the doping profile in a base layer in the metamorphic solar cell according to the present invention; and

FIG. 17 is a graph of the predicted quantum efficiency versus wavelength of the bottom cell of an inverted metamorphic solar cell with a MQW according to the present invention, versus a cell without a MQW.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner.

Moreover, the drawings are not intended to depict every feature of the actual embodiment nor the relative dimensions of the depicted elements, and are not drawn to scale.

The basic concept of fabricating an inverted metamorphic multijunction (IMM) solar cell is to grow the subcells of the solar cell on a substrate in a “reverse” sequence. That is, the high band gap subcells (i.e. subcells with band gaps in the range of 1.8 to 2.1 eV), which would normally be the “top” subcells facing the solar radiation, are grown epitaxially on a semiconductor growth substrate, such as for example GaAs or Ge, and such subcells are therefore lattice-matched to such substrate. One or more lower band gap middle subcells (i.e. with band gaps in the range of 1.2 to 1.8 eV) can then be grown on the high band gap subcells.

At least one lower subcell is formed over the middle subcell such that the at least one lower subcell is substantially lattice-mismatched with respect to the growth substrate and such that the at least one lower subcell has a third lower band gap (i.e. a band gap in the range of 0.7 to 1.2 eV). A surrogate substrate or support structure is provided over the “bottom” or substantially lattice-mismatched lower subcell, and the growth semiconductor substrate is subsequently removed. (The growth substrate may then subsequently be re-used for the growth of a second and subsequent solar cells).

The present invention is directed to the structures and processes for improving and optimizing the efficiency of the bottom or other low band gap subcells of an IMM structure.

The bottom subcell (i.e., the subcell of lowest band gap) should not control the J_{sc} of the composite cell, that is, the bottom subcell's J_{sc} must be greater than that of one of the other subcells. To establish this condition, the collection efficiency of the bottom subcell must be carefully defined, and the material compositions, structures, and process parameters selected to achieve the desired band gap. Some approaches used in the present invention include optimizing material quality, including a collection field, creating a reflective back contact, instituting a heterojunction, and reducing reflection.

In the preferred embodiment of the present invention, another means of increasing the absorbable photon flux is to incorporate a multiple quantum well with conduction and valence energy states separated by less than the bottom subcell's band gap energy. This inclusion has the advantage of increasing the absorption bandwidth for the bottom subcell without reducing its band gap and theoretically its contribution to the cell's V_{oc}. In some implementations, the same structures may be implemented in other low band gap subcells.

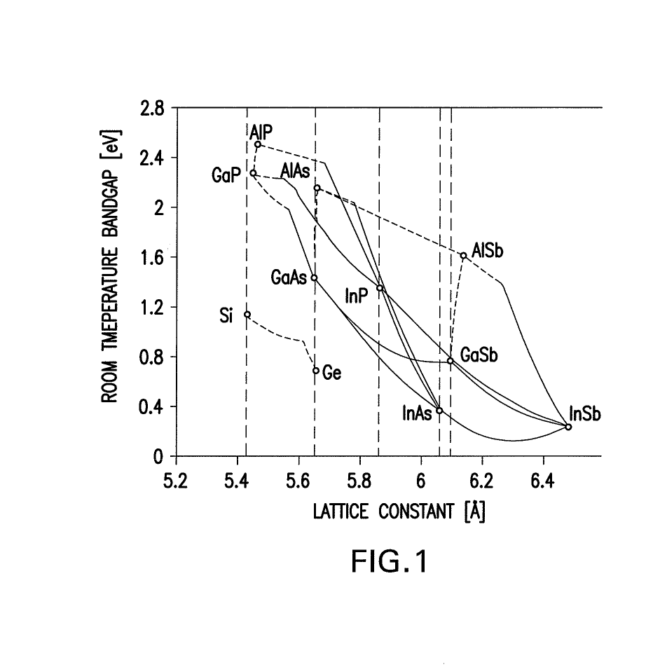

FIG. 1 is a graph representing the band gap of certain binary materials and their lattice constants. The band gap and lattice constants of ternary materials are located on the lines drawn between typical associated binary materials (such as the ternary material GaAlAs being located between the GaAs and AlAs points on the graph, with the band gap of the ternary material lying between 1.42 eV for GaAs and 2.16 eV for AlAs depending upon the relative amount of the individual constituents). Thus, depending upon the desired band gap, the material constituents of ternary materials can be appropriately selected for growth.

The lattice constants and electrical properties of the layers in the semiconductor structure are preferably controlled by specification of appropriate reactor growth temperatures and times, and by use of appropriate chemical composition and dopants. The use of a vapor deposition method, such as Organo Metallic Vapor Phase Epitaxy (OMVPE), Metal Organic Chemical Vapor Deposition (MOCVD), Molecular Beam Epitaxy (MBE), or other vapor deposition methods for the reverse growth may enable the layers in the monolithic semiconductor structure forming the cell to be grown with the required thickness, elemental composition, dopant concentration and grading and conductivity type.

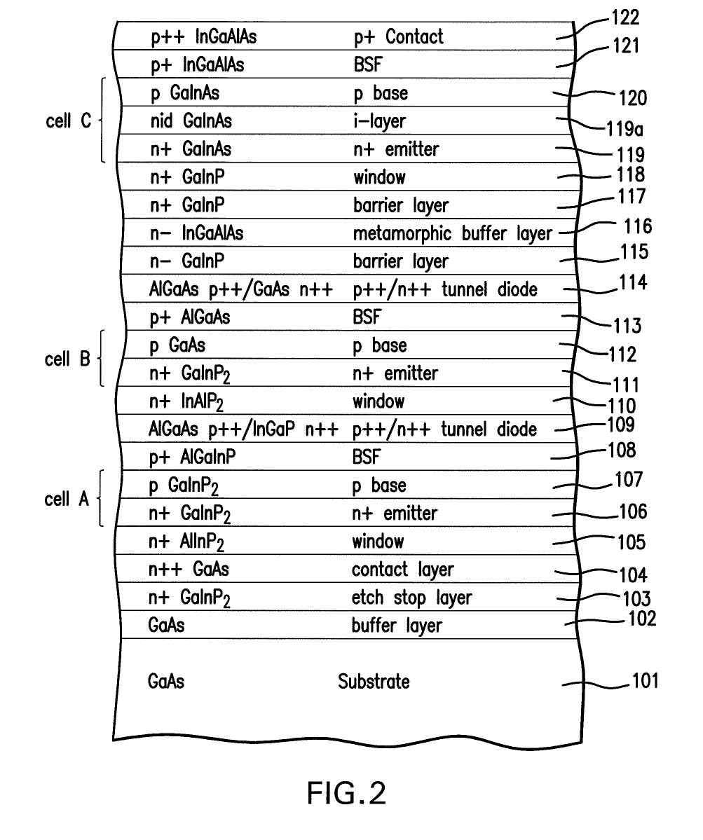

FIG. 2 depicts the multifunction solar cell according to the present invention after the sequential formation of the three subcells A, B and C on a GaAs growth substrate. More particularly, there is shown a substrate 101, which is preferably gallium arsenide (GaAs), but may also be germanium (Ge) or other suitable material. For GaAs, the substrate is preferably a 15° off-cut substrate, that is to say, its surface is orientated 15° off the (100) plane towards the (111)A plane, as more fully described in U.S. patent application Ser. No. 12/047,944, filed Mar. 13, 2008.

In the case of a Ge substrate, a nucleation layer (not shown) is deposited directly on the substrate 101. On the substrate, or over the nucleation layer (in the case of a Ge substrate), a buffer layer 102 and an etch stop layer 103 are further deposited. In the case of GaAs substrate, the buffer layer 102 is preferably GaAs. In the case of Ge substrate, the buffer layer 102 is preferably InGaAs. A contact layer 104 of GaAs is then deposited on layer 103, and a window layer 105 of AlInP is deposited on the contact layer. The subcell A, consisting of an n+ emitter layer 106 and a p-type base layer 107, is then epitaxially deposited on the window layer 105. The subcell A is generally latticed matched to the growth substrate 101.

It should be noted that the multifunction solar cell structure could be formed by any suitable combination of group III to V elements listed in the periodic table subject to lattice constant and bandgap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorous (P), arsenic (As), antimony (Sb), and bismuth (Bi).

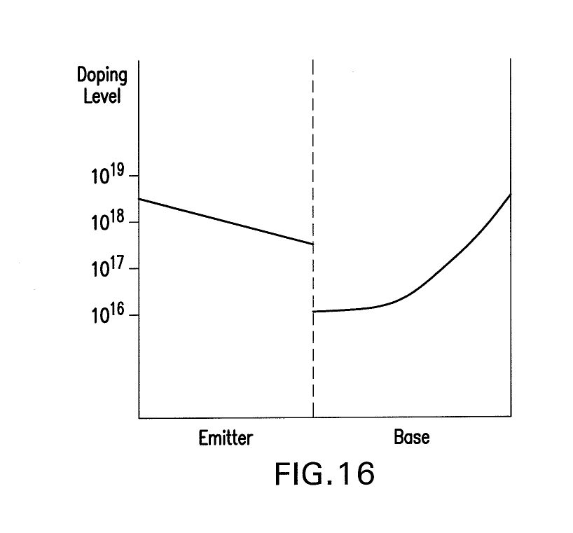

In the preferred embodiment, the emitter layer 106 is composed of InGa(Al)P and the base layer 107 is composed of InGa(Al)P. The aluminum or Al term in parenthesis in the preceding formula means that Al is an optional constituent, and in this instance may be used in an amount ranging from 0% to 30%. The doping profile of the emitter and base layers 106 and 107 according to the present invention will be discussed in conjunction with FIG. 16.

Subcell A will ultimately become the “top” subcell of the inverted metamorphic structure after completion of the process steps according to the present invention to be described hereinafter.

On top of the base layer 107 a back surface field (“BSF”) layer 108 is deposited and used to reduce recombination loss, preferably p+ Al GaInP.

The BSF layer 108 drives minority carriers from the region near the base/BSF interface surface to minimize the effect of recombination loss. In other words, a BSF layer 18 reduces recombination loss at the backside of the solar subcell A and thereby reduces the recombination in the base.

On top of the BSF layer 108 is deposited a sequence of heavily doped p-type and n-type layers 109 which forms a tunnel diode which is an ohmic circuit element to connect subcell A to subcell B. These layers are preferably composed of p++ Al GaAs, and n++ InGaP.

On top of the tunnel diode layers 109 a window layer 110 is deposited, preferably n+ InAlP. The window layer 110 used in the subcell B operates to reduce the interface recombination loss. It should be apparent to one skilled in the art, that additional layer(s) may be added or deleted in the cell structure without departing from the scope of the present invention.

On top of the window layer 110 the layers of subcell B are deposited: the n-type emitter layer 111 and the p-type base layer 112. These layers are preferably composed of InGaP and In_{0.015}GaAs respectively (for a Ge substrate or growth template), or InGaP and GaAs respectively (for a GaAs substrate), although any other suitable materials consistent with lattice constant and bandgap requirements may be used as well. Thus, subcell B may be composed of a GaAs, GaInP, GaInAs, GaAsSb, or GaInAsN emitter region and a GaAs, GaInAs, GaAsSb, or GaInAsN base region. The doping profile of layers 111 and 112 according to the present invention will be discussed in conjunction with FIG. 16.

In the preferred embodiment of the present invention, the middle subcell emitter has a band gap equal to the top subcell emitter, and the bottom subcell emitter has a band gap greater than the band gap of the base of the middle subcell. Therefore, after fabrication of the solar cell, and implementation and operation, neither the middle subcell B nor the bottom subcell C emitters will be exposed to absorbable radiation. Substantially radiation will be absorbed in the bases of cells B and C, which have narrower band gaps then the emitters. Therefore, the advantages of using heterojunction subcells are: 1) the short wavelength response for both subcells will improve, and 2) the bulk of the radiation is more effectively absorbed and collected in the narrower band gap base. The effect will be to increase J_{sc}.

On top of the cell B is deposited a BSF layer 113 which performs the same function as the BSF layer 109. A p++/n++ tunnel diode 114 is deposited over the BSF layer 113 similar to the layers 109, again forming an ohmic circuit element to connect subcell B to subcell C. These layers 114 are preferably compound of p++ Al GaAs and n++ InGaP.

A barrier layer 115, preferably composed of n-type InGa(Al)P, is deposited over the tunnel diode 114, to a thickness of about 1.0 micron. Such barrier layer is intended to prevent threading dislocations from propagating, either opposite to the direction of growth into the middle and top subcells B and C, or in the direction of growth into the bottom subcell A, and is more particularly described in copending U.S. patent application Ser. No. 11/860,183, filed Sep. 24, 2007.

A metamorphic layer (or graded interlayer) 116 is deposited over the barrier layer 115 using a surfactant. Layer 116 is preferably a compositionally step-graded series of InGaAlAs layers, preferably with monotonically changing lattice constant, so as to achieve a gradual transition in lattice constant in the semiconductor structure from subcell B to subcell C while minimizing threading dislocations from occurring. The bandgap of layer 116 is constant throughout its thickness preferably approximately 1.5 eV or otherwise consistent with a value slightly greater than the bandgap of the middle subcell B. The preferred embodiment of the graded interlayer may also be expressed as being composed of (InₓGa₁₋ₓ)_{y}Al_{1-y}As, with x and y selected such that the band gap of the interlayer remains constant at approximately 1.50 eV.

In the surfactant assisted growth of the metamorphic layer 116, a suitable chemical element is introduced into the reactor during the growth of layer 116 to improve the surface characteristics of the layer. In the preferred embodiment, such element may be a dopant or donor atom such as selenium (Se) or tellurium (Te). Small amounts of Se or Te are therefore incorporated in the metamorphic layer 116 at the end of the growth process, and remain in the finished solar cell. Although Se or Te are the preferred n-type dopant atoms, other non-isoelectronic surfactants may be used as well.

Surfactant assisted growth results in a much smoother or planarized surface. Since the surface topography affects the bulk properties of the semiconductor material as it grows and the layer becomes thicker, the use of the surfactants minimizes threading dislocations in the active regions, and therefore improves overall solar cell efficiency.

As an alternative to the use a non-isoelectronic surfactant one may use an isoelectronic surfactant. The term “isoelectronic” refers to surfactants such as antimony (Sb) or bismuth (Bi), since such elements have the same number of valence electrons as the P of InGaP, or as in InGaAlAs, in the metamorphic buffer layer. Such Sb or Bi surfactants will not typically be incorporated into the metamorphic layer 116.

In an alternative embodiment where the solar cell has only two subcells, and the “middle” cell B is the uppermost or top subcell in the final solar cell, wherein the “top” subcell B would typically have a bandgap of 1.8 to 1.9 eV, then the band gap of the interlayer would remain constant at 1.9 eV.

In the inverted metamorphic structure described in the Wanlass et al. paper cited above, the metamorphic layer consists of nine compositionally graded InGaP steps, with each step layer having a thickness of 0.25 micron. As a result, each layer of Wanlass et al. has a different bandgap. In the preferred embodiment of the present invention, the layer 116 is composed of a plurality of layers of InGaAlAs, with monotonically changing lattice constant, each layer having the same bandgap, approximately 1.5 eV.

The advantage of utilizing a constant bandgap material such as InGaAlAs is that arsenide-based semiconductor material is much easier to process in standard commercial MOCVD reactors, while the small amount of aluminum assures radiation transparency of the metamorphic layers.

Although the preferred embodiment of the present invention utilizes a plurality of layers of InGaAlAs for the metamorphic layer 116 for reasons of manufacturability and radiation transparency, other embodiments of the present invention may utilize different material systems to achieve a change in lattice constant from subcell B to subcell C. Thus, the system of Wanlass using compositionally graded InGaP is a second embodiment of the present invention. Other embodiments of the present invention may utilize continuously graded, as opposed to step graded, materials. More generally, the graded interlayer may be composed of any of the As, P, N, Sb based III-V compound semiconductors subject to the constraints of having the in-plane lattice parameter greater or equal to that of the second solar cell and less than or equal to that of the third solar cell, and having a bandgap energy greater than that of the second solar cell.

In another embodiment of the present invention, an optional second barrier layer 117 may be deposited over the InGaAlAs metamorphic layer 116. The second barrier layer 117 will typically have a different composition than that of barrier layer 115, and performs essentially the same function of preventing threading dislocations from propagating. In the preferred embodiment, barrier layer 117 is n+ type GaInP.

A window layer 118 preferably composed of n+ type GaInP is then deposited over the barrier layer 117 (or directly over layer 116, in the absence of a second barrier layer). This window layer operates to reduce the recombination loss in subcell “C”. It should be apparent to one skilled in the art that additional layers may be added or deleted in the cell structure without departing from the scope of the present invention.

On top of the window layer 118, the layers of cell C are deposited: the n+ emitter layer 119, an i-layer or unintentionally doped layer 119a, and the p-type base layer 120. The emitter and base layers are preferably composed of n+ type InGaP and p type InGaAs, forming a heterojunction subcell, although another suitable materials consistent with lattice constant and bandgap requirements may be used as well. The doping profile of layers 119 and 120 will be discussed in connection with FIG. 16.

The i-layer region is composed of the strain balanced multiple quantum well or MQW. The two component alloys forming the MQW have opposite strain (tensile or compressive) such that their average lattice constant equals the lattice constant of the respective subcell. The component layers must not exceed their critical thickness and remain completely unrelaxed. Moreover, the unintentionally doped MQW must remain in the depleted region. In the preferred embodiment, the present invention has a MQW composed 15 repeat layers of 18 nm of In_{x+0.15}GaAs and 18 nm of In_{x-0.15}GaAs, where x equals the In mole fraction of the n and p layers of the bottom subcell. For this case, the strain of each layer is plus or minus 0.01. The critical thickness for each layer is approximately 25 nm, as predicted in the papers of Matthews and Blakeslee Journal of Crystal Growth, 27, 118-125 (1974)). The large critical thickness and subsequently thick component layers will result in an increased bottom subcell bandwidth. If we assume the elastic stiffness coefficients are equal for both alloys of the MQW, than the net tangential stress will be zero. For this structure with x=0.28 (i.e., with a band gap nominally 1.0 eV) and a 180 nm component layer thickness, the absorption band gap of the bottom subcell is expected to be extended by approximately 100 meV, i.e. to approximately 0.9 eV.

A BSF layer 121, preferably composed of InGaAlAs, is then deposited on top of the cell C, the BSF layer performing the same function as the BSF layers 108 and 113.

Finally a high band gap contact layer 122, preferably composed of InGaAlAs, is deposited on the BSF layer 121.

This contact layer 122 added to the bottom (non-illuminated) side of a lower band gap photovoltaic cell, in a single or a multijunction photovoltaic cell, can be formulated to reduce absorption of the light that passes through the cell, so that (1) with an ohmic metal contact layer below (non-illuminated side) it will also act as a mirror layer, and (2) the contact layer doesn't have to be selectively etched off, to prevent absorption.

It should be apparent to one skilled in the art, that additional layer(s) may be added or deleted in the cell structure without departing from the scope of the present invention.

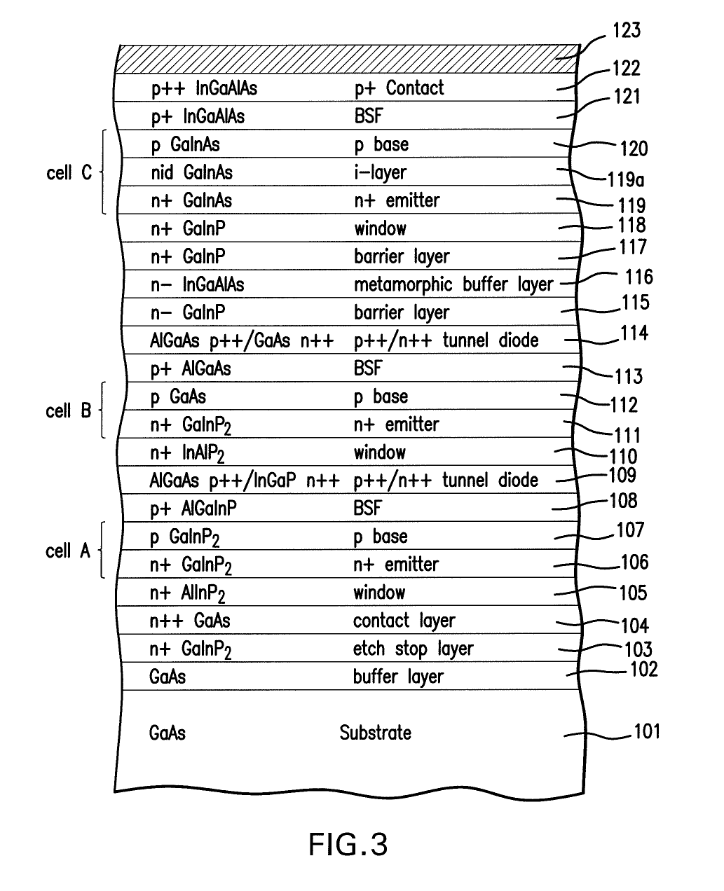

FIG. 3 is a cross-sectional view of the solar cell of FIG. 2 after the next process step in which a metal contact layer 123 is deposited over the p+ semiconductor contact layer 122. The metal is preferably the sequence of metal layers Ti/Au/Ag/Au.

Also, the metal contact scheme chosen is one that has a planar interface with the semiconductor, after heat treatment to activate the ohmic contact. This is done so that (1) a dielectric layer separating the metal from the semiconductor doesn't have to be deposited and selectively etched in the metal contact areas; and (2) the contact layer is specularly reflective over the wavelength range of interest.

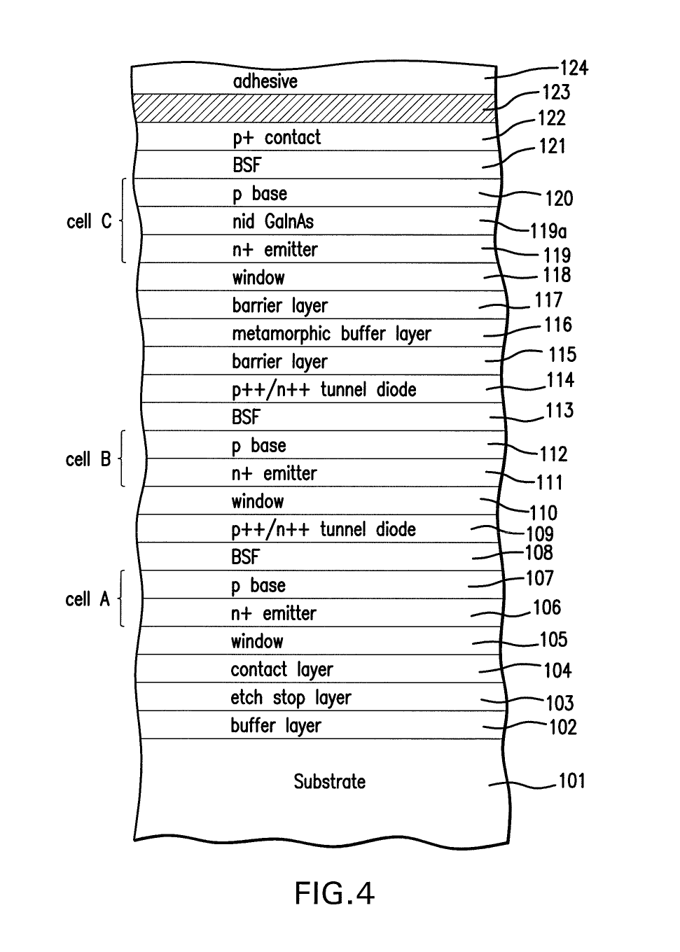

FIG. 4 is a cross-sectional view of the solar cell of FIG. 3 after the next process step in which an adhesive layer 124 is deposited over the metal layer 123. The adhesive is preferably Wafer Bond (manufactured by Brewer Science, Inc. of Rolla, Mo.).

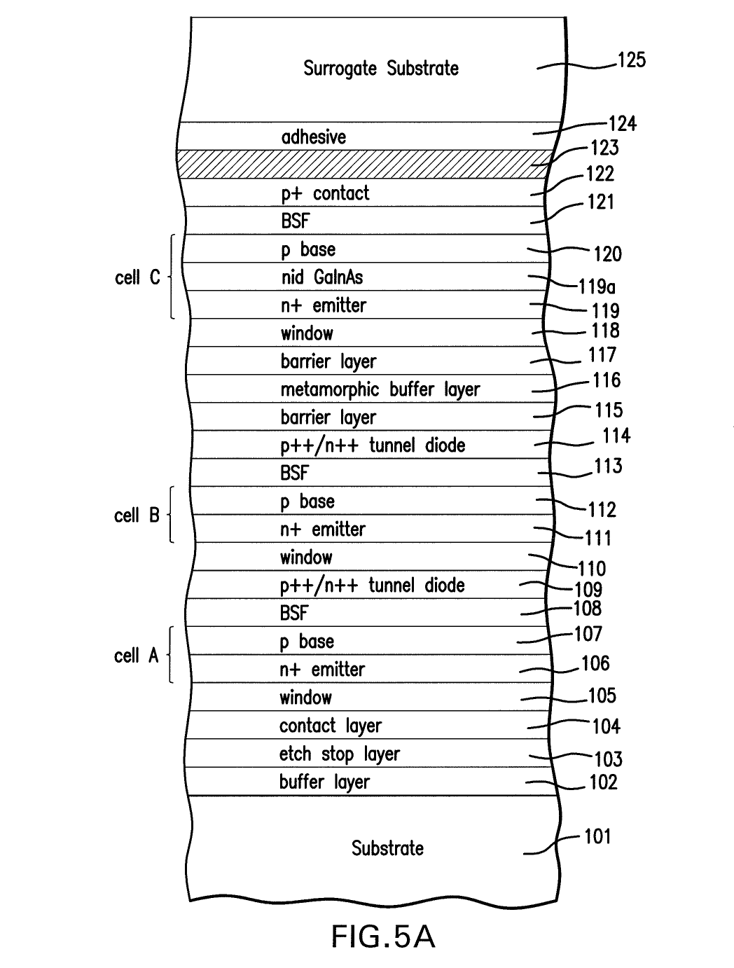

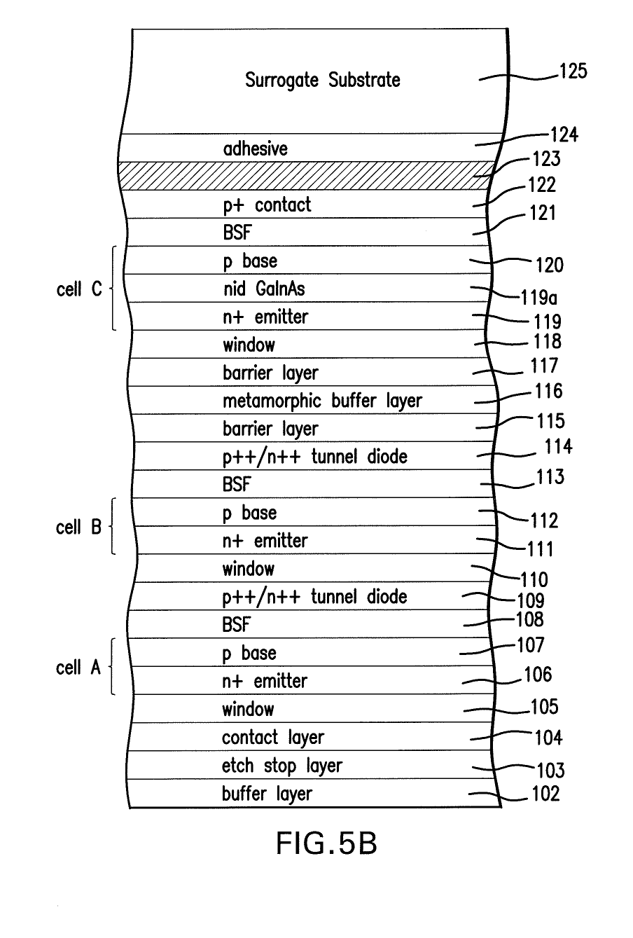

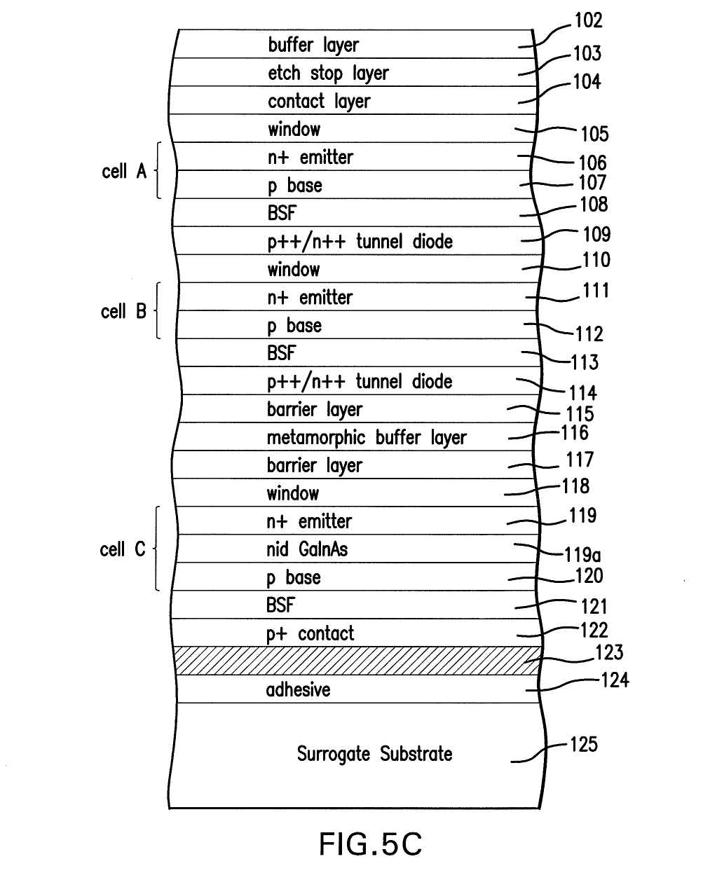

FIG. 5A is a cross-sectional view of the solar cell of FIG. 4 after the next process step in which a surrogate substrate 125, preferably sapphire, is attached. Alternative, the surrogate substrate may be GaAs, Ge or Si, or other suitable material. The surrogate substrate is about 40 mils in thickness, and is perforated with holes about 1 mm in diameter, spaced 4 mm apart, to aid in subsequent removal of the adhesive and the substrate. As an alternative to using an adhesive layer 124, a suitable substrate (e.g., GaAs) may be eutectically bonded to the metal layer 123.

FIG. 5B is a cross-sectional view of the solar cell of FIG. 5A after the next process step in which the original substrate is removed by a sequence of lapping and/or etching steps in which the substrate 101, and the buffer layer 103 are removed. The choice of a particular etchant is growth substrate dependent.

FIG. 5C is a cross-sectional view of the solar cell of FIG. 5B with the orientation with the surrogate substrate 125 being at the bottom of the Figure. Subsequent Figures in this application will assume such orientation.

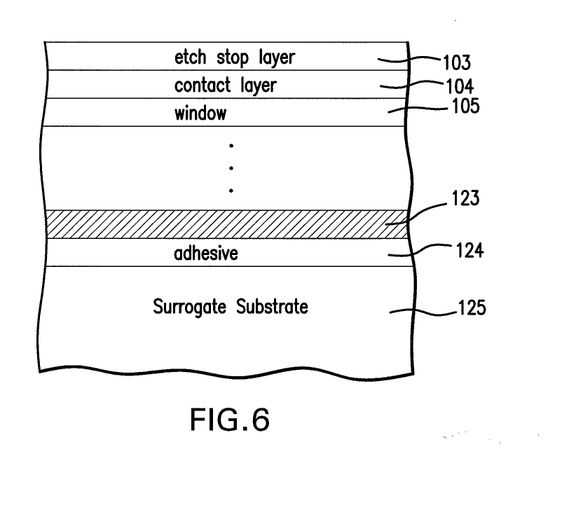

FIG. 6 is a simplified cross-sectional view of the solar cell of FIG. 5B depicting just a few of the top layers and lower layers over the surrogate substrate 125.

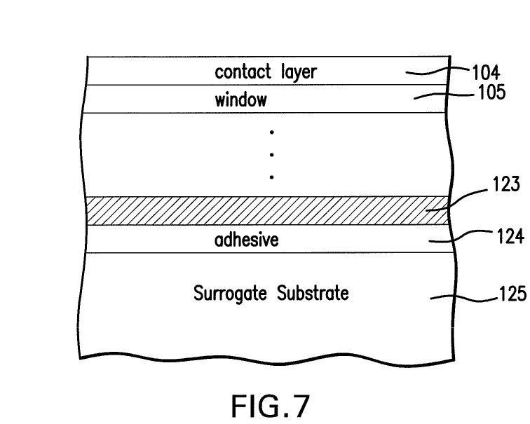

FIG. 7 is a cross-sectional view of the solar cell of FIG. 6 after the next process step in which the etch stop layer 103 is removed by a HCl/H₂O solution.

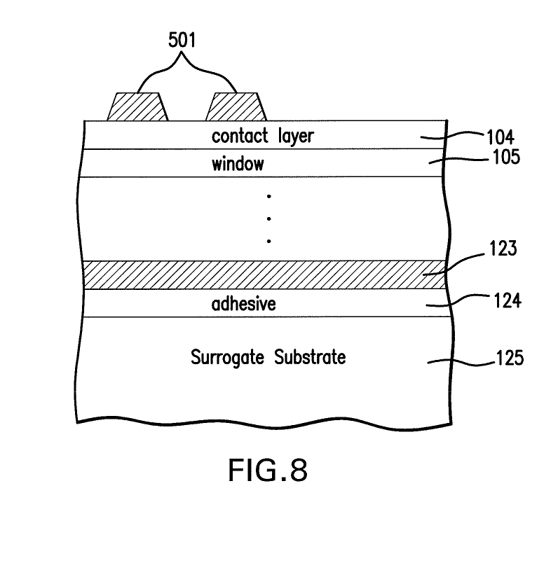

FIG. 8 is a cross-sectional view of the solar cell of FIG. 7 after the next sequence of process steps in which a photoresist mask (not shown) is placed over the contact layer 104 to form the grid lines 501. As will be described in greater detail below, the grid lines 501 are deposited via evaporation and lithographically patterned and deposited over the contact layer 104. The mask is subsequently lifted off to form the finished metal grid lines 501 as depicted in the Figures.

As more fully described in U.S. patent application Ser. No. 12/218,582 filed Jul. 18, 2008, hereby incorporated by reference, the grid lines 501 are preferably composed of Pd/Ge/Ti/Pd/Au, although other suitable materials may be used as well.

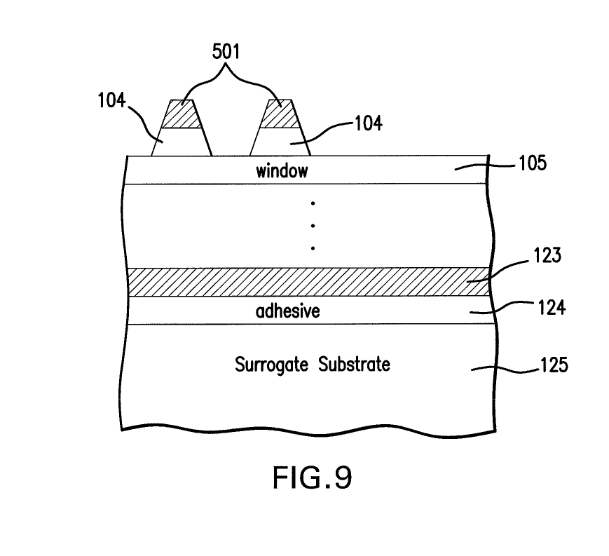

FIG. 9 is a cross-sectional view of the solar cell of FIG. 8 after the next process step in which the grid lines are used as a mask to etch down the surface to the window layer 105 using a citric acid/peroxide etching mixture.

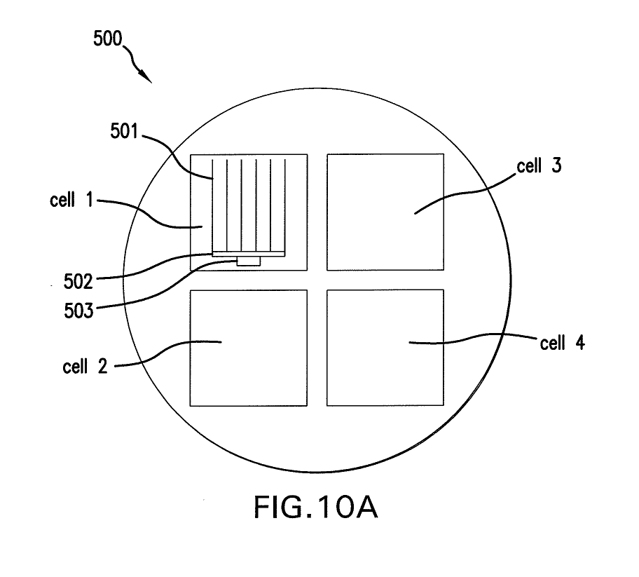

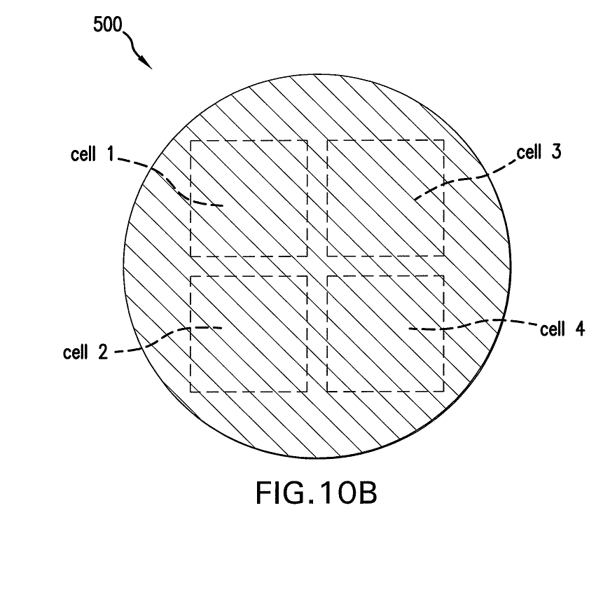

FIG. 10A is a top plan view of a wafer in which four solar cells are implemented. The depiction of four cells is for illustration for purposes only, and the present invention is not limited to any specific number of cells per wafer.

In each cell there are grid lines 501 (more particularly shown in cross-section in FIG. 9), an interconnecting bus line 502, and a contact pad 503. The geometry and number of grid and bus lines and the contact pad are illustrative and the present invention is not limited to the illustrated embodiment.

FIG. 10B is a bottom plan view of the wafer with four solar cells shown in FIG. 10A.

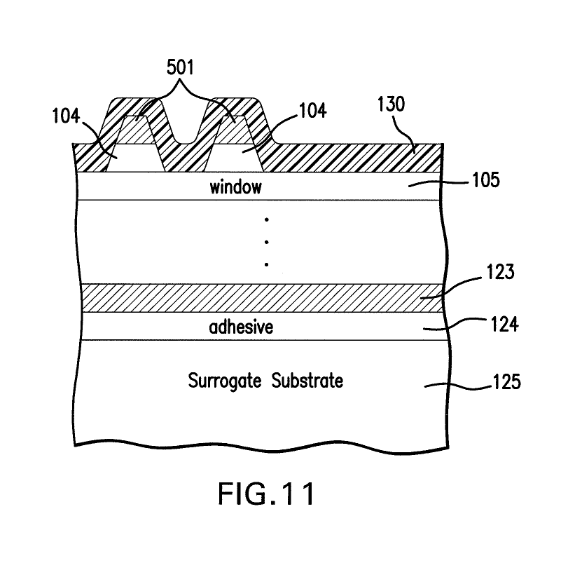

FIG. 11 is a cross-sectional view of the solar cell of FIG. 9 after the next process step in which an antireflective (ARC) dielectric coating layer 130 is applied over the entire surface of the “bottom” side of the wafer with the grid lines 501.

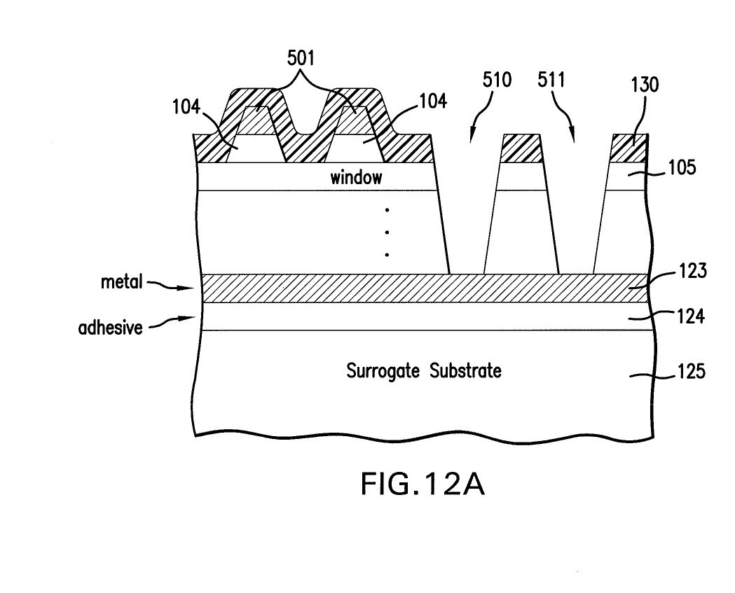

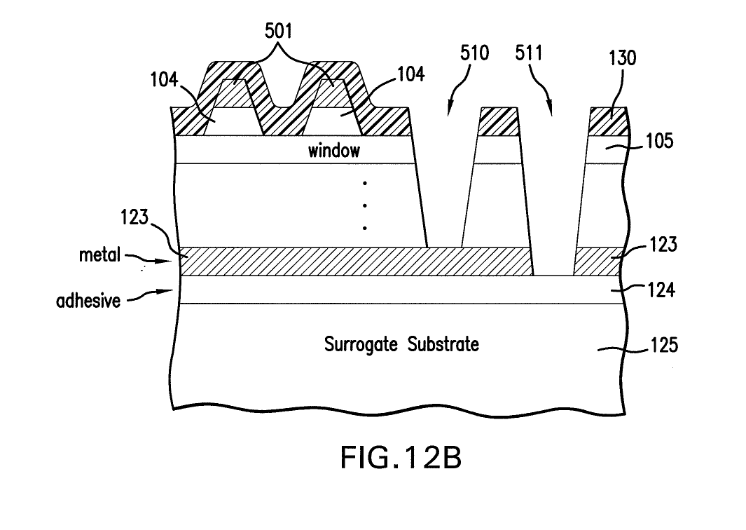

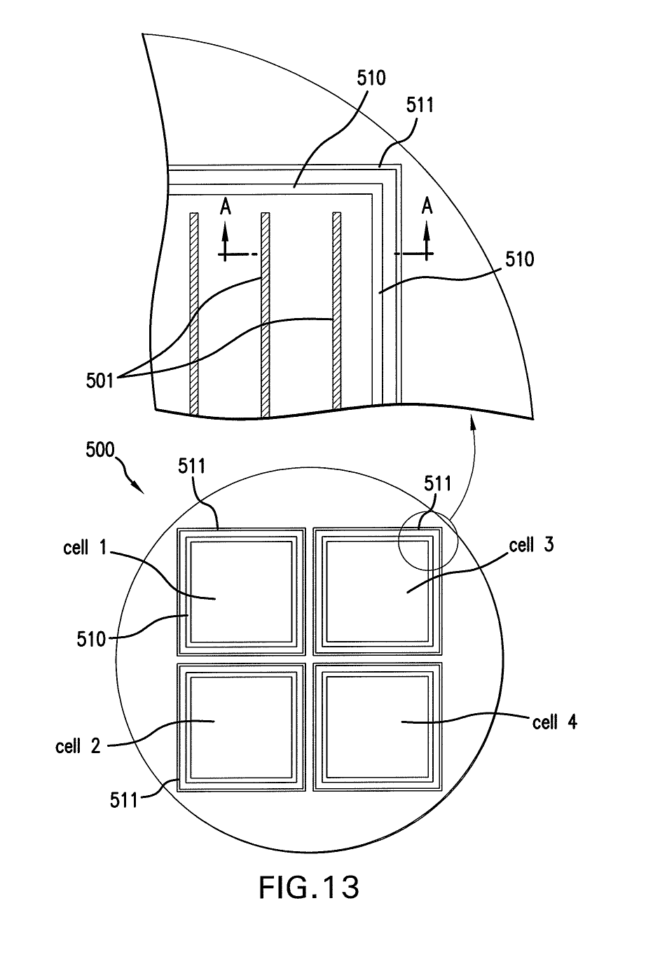

FIG. 12A is a cross-sectional view of the solar cell of FIG. 11 after the next process step according to the present invention in which first and second annular channels 510 and 511, or portions of the semiconductor structure, are etched down to the metal layer 123 using phosphide and arsenide etchants. These channels define a peripheral boundary between the cell and the rest of the wafer, and leaves a mesa structure which constitutes the solar cell. The cross-section depicted in FIG. 12A is that as seen from the A-A plane shown in FIG. 13.

FIG. 12B is a cross-sectional view of the solar cell of FIG. 12A after the next process step in which channel 511 is exposed to a metal etchant, layer 123 in the channel 511 is removed, and channel 511 is extended in depth approximately the top surface of the adhesive layer 124.

FIG. 13 is a top plan view of the wafer of FIGS. 12A and 12B depicting the channels 510 and 511 etched around the periphery of each cell.

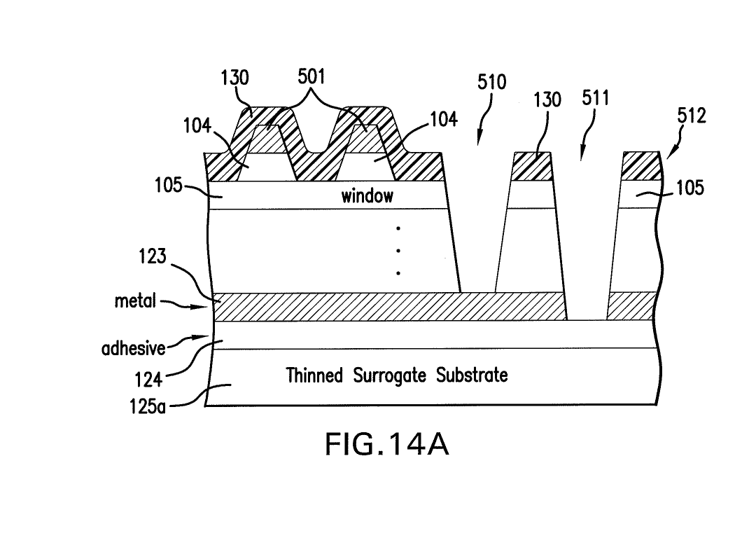

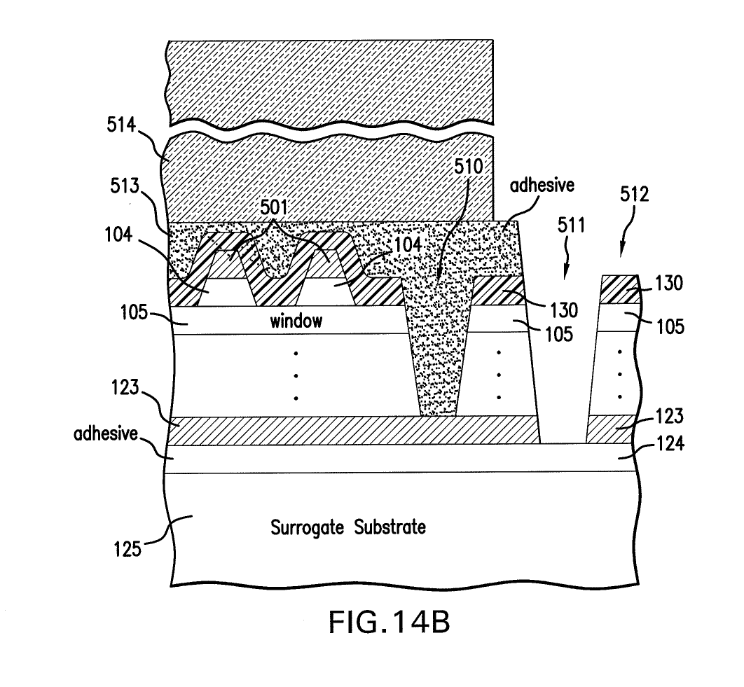

FIG. 14A is a cross-sectional view of the solar cell of FIG. 12 after the next process step in a first embodiment of the present invention in which the surrogate substrate 125 is appropriately thinned to a relatively thin layer 125a, by grinding, lapping, or etching.

FIG. 14B is a cross-sectional view of the solar cell of FIG. 14A after the next process step in a second embodiment of the present invention in which a cover glass 513 is secured to the top of the cell by an adhesive. The cover glass 513 preferably covers the entire channel 510, but does not extend to channel 511.

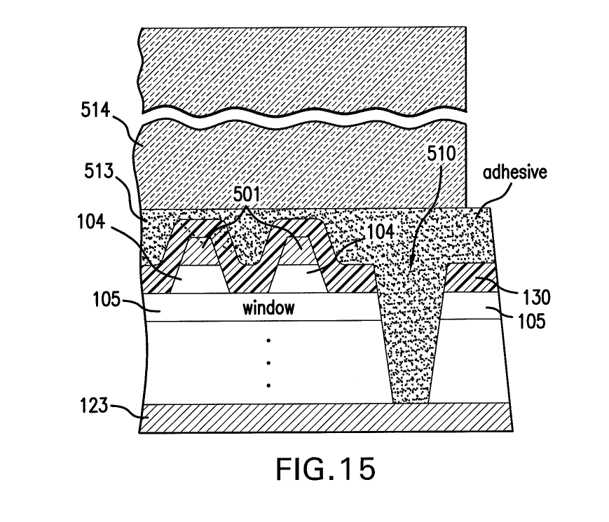

FIG. 15 is a cross-sectional view of the solar cell of FIG. 14B after the next process step of the present invention in which the adhesive layer 124, the surrogate substrate 125 and the peripheral portion 512 of the wafer is entirely removed, leaving only the solar cell with the cover glass 513 on the top, and the metal contact layer 123 on the bottom, which forms the backside contact of the solar cell. The surrogate substrate may be reused in subsequent wafer processing operations.

FIG. 16 is a graph of a doping profile in the emitter and base layers in one or more subcells of the inverted metamorphic multifunction solar cell of the present invention. The various doping profiles within the scope of the present invention, and the advantages of such doping profiles are more particularly described in copending U.S. patent application Ser. No. 11/956,069 filed Dec. 13, 2007, herein incorporated by reference. The doping profiles depicted herein are merely illustrative, and other more complex profiles may be utilized as would be apparent to those skilled in the art without departing from the scope of the present invention.

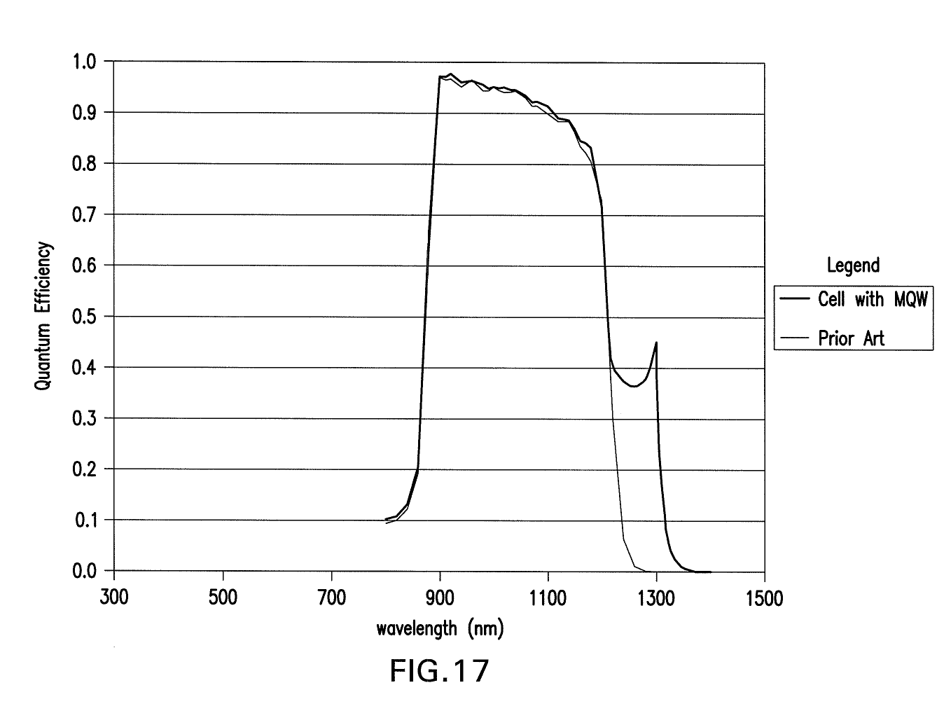

FIG. 17 is a graph of the predicted quantum efficiency versus wavelength of the bottom cell of an inverted metamorphic solar cell with a MQW according to the present invention, versus a cell without a MQW. The cell with a MQW is predicted to have an increase in quantum efficiency and a sharp peak in the wavelength range from 1250 to 1300 nm, based on an analysis of the quantum efficiency graphs of similar MQW structures.

It will be understood that each of the elements described above, or two or more together, also may find a useful application in other types of constructions differing from the types of constructions described above.

Although the preferred embodiment of the present invention utilizes a vertical stack of three subcells, the present invention can apply to stacks with fewer or greater number of subcells, i.e. two junction cells, four junction cells, five junction cells, etc. In the case of four or more junction cells, the use of more than one metamorphic grading interlayer may also be utilized.

In addition, although the present embodiment is configured with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, the present invention may utilize an arrangement of one or more, or all, homojunction cells or subcells, i.e., a cell or subcell in which the p-n junction is formed between a p-type semiconductor and an n-type semiconductor both of which have the same chemical composition and the same band gap, differing only in the dopant species and types, and one or more heterojunction cells or subcells. Subcell A, with p-type and n-type InGaP is one example of a homojunction subcell. Alternatively, as more particularly described in U.S. patent application Ser. No. 12/023,772 filed Jan. 31, 2008, the present invention may utilize one or more, or all, heterojunction cells or subcells, i.e., a cell or subcell in which the p-n junction is formed between a p-type semiconductor and an n-type semiconductor having different chemical compositions of the semiconductor material in the n-type regions, and/or different band gap energies in the p-type regions, in addition to utilizing different dopant species and type in the p-type and n-type regions that form the p-n junction.

The composition of the window or BSF layers may utilize other semiconductor compounds, subject to lattice constant and band gap requirements, and may include AlInP, AlAs, A1P, AlGaInP, AlGaAsP, AlGaInAs, AlGaInPAs, GaInP, GaInAs, GaInPAs, AlGaAs, AlInAs, AlInPAs, GaAsSb, AlAsSb, GaAlAsSb, AlInSb, GaInSb, AlGaInSb, AlN, GaN, InN, GaInN, AlGaInN, GaInNAs, AlGaInNAs, ZnSSe, CdSSe, and similar materials, and still fall within the spirit of the present invention.

While the invention has been illustrated and described as embodied in a inverted metamorphic multifunction solar cell, it is not intended to be limited to the details shown, since various modifications and structural changes may be made without departing in any way from the spirit of the present invention.

Thus, while the description of this invention has focused primarily on solar cells or photovoltaic devices, persons skilled in the art know that other optoelectronic devices, such as thermophotovoltaic (TPV) cells, photodetectors and light-emitting diodes (LEDS) are very similar in structure, physics, and materials to photovoltaic devices with some minor variations in doping and the minority carrier lifetime. For example, photodetectors can be the same materials and structures as the photovoltaic devices described above, but perhaps more lightly-doped for sensitivity rather than power production. On the other hand LEDs and also be made with similar structures and materials, but perhaps more heavily-doped to shorten recombination time, thus radiative lifetime to produce light instead of power. Therefore, this invention also applies to photodetectors and LEDs with structures, compositions of matter, articles of manufacture, and improvements as described above for photovoltaic cells.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A method of manufacturing a solar cell comprising:
providing a first semiconductor substrate for the epitaxial growth of semiconductor material;
forming a first subcell on said substrate comprising a first semiconductor material with a first band gap and a first lattice constant;
forming a second subcell comprising a second semiconductor material with a second band gap and a second lattice constant, wherein the second band gap is less than the first band gap and the second lattice constant is greater than the first lattice constant; said second subcell including a strain balance quantum well structure; and
forming a lattice constant transition material positioned between the first subcell and the second subcell, said lattice constant transition material having a lattice constant that changes gradually from the lattice constant to the second lattice constant.

2. A method as defined in claim 1, further comprising attaching a surrogate second substrate over the second subcell and removing said first substrate.

3. A method as defined in claim 1, wherein said first subcell is composed of an GaInP, GaSa, GaInAs, GaAsSb, or GaInAsN emitter region and an GaAs, GaInAs, GaAsSb, or GaInAsN base region.

4. A method as defined in claim 1, wherein the second subcell is composed of an nip structure with InGaAs base and emitter regions.

5. A method as defined in claim 1, wherein said transition material is composed of any of the As, P, N, Sb based III-V compound semiconductors subject to the constraints of having the in-plane lattice parameter greater or equal to that of the first subcell and less than or equal to that of the second subcell, and having a band gap energy greater than that of the first subcell.

6. A method as defined in claim 1, wherein the transition material is composed of (InₓGa₁₋ₓ)_{y}As, with x and y selected such that the band gap of the transition material remains constant at a band gap energy greater than that of said first subcell.

7. A method as defined in claim 1, wherein the band gap of the transition material remains constant at approximately 1.50 eV.

8. A method as defined in claim 1, wherein said strain balanced quantum well structure includes repeating layers of In_{x-0.15}GaAs and In_{x+0.15}GaAs, where x is the In mole fraction of the n and p layers of the second subcell.

9. A method as defined in claim 1, wherein said strain balanced quantum well structure includes at least fifteen layers, each approximately 18 nm thick.

10. A method as defined in claim 1, wherein said strain balanced quantum well structure includes a sequence of first and second different semiconductor layers with compressively strained and tensionally strained layers, respectively.

11. A method as defined in claim 1 wherein the average strain of the sequence of first and second difference semiconductor layers is approximately equal to zero.

12. A method as defined in claim 1, wherein said strain balanced quantum well structure is approximately 180 nm thick.

13. A method of forming a multijunction solar cell comprising an upper subcell, a middle subcell, and a lower subcell comprising:
providing a first substrate for the epitaxial growth of semiconductor material;
forming an upper first solar subcell on said first substrate having a first band gap;
forming a middle second solar subcell over said first solar subcell having a second band gap smaller than said first band gap;
forming a graded interlayer over said second solar cell;
forming a lower third solar subcell over said graded interlayer having a fourth band gap smaller than said second band gap such that said third subcell is lattice mismatched with respect to said second subcell; wherein the third solar subcell includes an unintentionally doped layer disposed between its base and emitter;
attaching a surrogate second substrate over said third solar subcell; and
removing said first substrate.

14. The method as defined in claim 13, wherein the graded interlayer has a third band gap greater than said second band gap.

15. The method as defined in claim 13, further comprising etching a first trough around the periphery of said solar cell to the surrogate second substrate so as to form a mesa structure on said surrogate second substrate and facilitate the removal of said solar cell from the surrogate second substrate; etching a second trough around the periphery of said solar cell so as to form a mesa structure on said surrogate second substrate, wherein the second trough lies inside the periphery of the first trough, wherein the dept of the second trough extends down to said contact metal layer.

16. The method as defined in claim 13, wherein the contact metal layer is composed of a sequence of layers including the sequence Pd/Ge/Ti/Pd, and the depth of the first trough extends down to the surface of the surrogate second substrate.

17. The method as defined in claim 16, further comprising mounting a cover glass over said upper first subcell extending to the edge of said first trough, comprising removing the surrogate second substrate, so that the periphery of the solar cell is defined by the first trough.

18. A method as defined in claim 13, wherein the upper subcell is composed of InGa(Al)P.

19. The method as defined in claim 13, wherein the middle subcell is composed of an GaAs, GaInP, GaInAs, GaAsSb, or GaInAsN emitter region and a GaAs, GaInAs, GaAsSb, or GaInAsN base region.

20. The method as defined in claim 13, wherein the lower solar subcell is composed of an InGaAs base and emitter layer, or a InGaAs base layer and a InGaP emitter layer.

21. The method as defined as claim 13, wherein the graded interlayer is compositionally graded to lattice match the middle subcell on one side and the lower subcell on the other side, and is composed of InGaAlAs.

22. The method as defined in claim 13, wherein the graded interlayer has approximately a 1.5 eV band gap throughout its thickness

23. The method as defined in claim 13, wherein the graded interlayer is composed of any of the As, P, N, Sb based III-V compound semiconductors subject to the constraints of having the in-plane lattice parameter greater or equal to that of the second solar cell and less than or equal to that of the second solar cell and less than or equal to that of the third solar cell, and having a band gap energy greater than that of the second solar cell.

24. A solar cell comprising:
a first semiconductor substrate for the epitaxial growth of semiconductor material;
a first subcell on the substrate including a first semiconductor material with a first band gap and a first lattice constant;
a second subcell including a second semiconductor material with a second band gap and a second lattice constant, wherein the second band gap is less than the first band gap and the second lattice constant is greater than the first lattice constant;
the second subcell including a strain balanced multiple quantum well structure; and
a lattice constant transition material positioned between the first subcell and the second subcell, the lattice constant transition material having a lattice constant that changes gradually from the lattice constant to the second lattice constant.

25. A solar cell as defined in claim 24, wherein said strain balanced quantum well structure includes repeating layers of In_{x-0.15}GaAs and In_{x+0.15}GaAs, where x is the in mole fraction of the n and p layers of the second subcell.

26. A solar cell as defined in claim 24, wherein said strain balanced quantum well structure includes at least fifteen layers, each approximately 18 nm thick.

27. A solar cell as defined in claim 24, wherein said strain balanced quantum well structure includes a sequence of first and second different semiconductor layers with compressively strained and tensionally strained layers, respectively.

28. A solar cell as defined in claim 28, wherein the lattice constant transition material has a band gap greater than the band gap of said middle subcell.

29. A solar cell as defined in claim 36, wherein the lattice constant transition material is composed of any of the As, P, N, Sb based III-V compound semiconductors subject to the constraints of having the in-plane lattice parameter greater or equal to that of the middle subcell and less than or equal to that of the bottom subcell.

30. A solar cell as defined in claim 36, wherein the lattice constant transition material is composed of (InₓGa₁₋ₓ)_{y}Al_{1-y}As, with x and y selected such that the band gap of the interlayer remains constant at approximately 1.50 eV.
